(19) United States
(12) Patent Application Publication
(10) Pub. No.: US 2001/0042503 A1
(43) Pub. Date: Nov. 22, 2001

(54) METHOD FOR DESIGN OF EPITAXIAL LAYER AND SUBSTRATE STRUCTURES FOR HIGH-QUALITY EPITAXIAL GROWTH ON LATTICE-MISMATCHED SUBSTRATES

(76) Inventors: YU-HWA LO, ITHACA, NY (US); FELIX EJECKMAN, ITHACA, NY (US); ZUHUA ZHU, ITHACA, NY (US)

Correspondence Address: FERNANDEZ & ASSOCIATES LLP, 1047 EL CAMINO REAL, SUITE 201, MENLO PARK, CA, 94025

(21) Appl. No.: 09/247,413

(22) Filed: Feb. 10, 1999

(51) Int. Cl. C30B 1/00; H01L 21/00; H01L 21/84

(52) U.S. Cl. 117/4; 438/162

(57) ABSTRACT

A method for forming low defect density epitaxial layers on lattice-mismatched substrates includes confining dislocations through interactions between the dislocations and the stress field in the epitaxial layer. This method is applicable to any heteroepitaxial material systems with any degree of lattice mismatch. The method includes choosing the desired epilayer and the top substrate layer for epitaxial growth, determining the lattice constant and thermal expansion coefficient of the final epilayer and the top substrate layer, bonding an additional substrate layer under the top substrate layer to form a composite substrate so that the desired epilayer has negative (positive) or zero thermal mismatch to the composite substrate if the lattice mismatch between the epilayer and the top substrate layer is positive (negative), and choosing a buffer layer to be deposited before the desired epilayer which is lattice matched to the epilayer. The chosen buffer layer should have a positive (negative) thermal mismatch to the entire substrate if the lattice mismatch is also positive (negative).

### FIELD OF THE INVENTION

The invention pertains to the field of semiconductor design. More particularly, the invention pertains to ensuring high-quality epitaxial growth on lattice mismatched substrates.

### BACKGROUND OF THE INVENTION

Many advanced semiconductor electronic and optoelectronic devices are made of epitaxial layers. A critical condition for obtaining high quality epitaxial layers is that the lattice constant of the epilayers has to be equal to that of the substrate. Even with a lattice mismatch as small as 1%, the density of defects in the epilayers can rise drastically when the epitaxial layers are thicker than a few hundred Angstroms. Over the years, the requirement of lattice match has severely limited the advance of semiconductor device technologies. Device performance is often compromised because the optimal epitaxial materials do not happen to have the same lattice constant as the substrate. As mixed-signal circuits and heterogeneously integrated systems-on-a-chip become the trend for future microelectronics, the inability to grow high-quality epitaxial layers on lattice-mismatched substrates (e.g., growing InP on Si) has made this development difficult and costly. In fact, forming high-quality epitaxial layers on lattice-mismatched substrates has been and will continue to be the foremost challenge for semiconductor material research.

Threading dislocations are the primary defects in the heteroepitaxial layers, although other types of defects such as stacking faults, micro twins, and anti-phase domains may also exist. To cope with the problem of threading dislocations, two approaches have been developed: one focusing on the epitaxial growth and the other focusing on the substrate design. Among the popular techniques in the first approach are the growth of buffer layers and growth on small mesas; and the techniques in the second approach include compliant substrates and stress-engineered substrates. Our invention, the co-design of the substrate and epitaxial layers, combines the merits of both approaches without the drawbacks of each. To appreciate the inherent merits of the new method, let us briefly review the existing approaches first.

Referring to FIG. 1, one popular buffer layer design uses a strain-graded buffered layer 12 to gradually transform the lattice constant from the value of the substrate 10 to the final desired value of epitaxial layer 14.

Referring to FIG. 2, another buffer layer design uses strained superlattices to bend threading dislocations. A buffer layer 21 joins a strained superlattice 22 to a substrate 20. A buffer layer 23 joins a strained superlattice 24 to strained superlattice 22. A device epitaxial layer 25 is grown on top of strained superlattice 24. A threading dislocation 26 shows a dislocation section 27 bent by superlattice 22 and a dislocation section 28 bent by superlattice 24.

These two approaches can be used jointly with the technique of mesa growth so that threading dislocations may either be bent or annihilated in the superlattice regions or be terminated at the periphery of the mesas. Although the strained superlattice and mesa growth methods have proved to be effective in reducing the number of threading dislocations, there still exist an appreciable amount of threading dislocations in the epilayers, severe enough to degrade the device performance and reliability. The effectiveness of the mesa growth is limited by the achievable mesa size. The first approach is most effective only when the mesa size is smaller than the epitaxial layer thickness. However, this condition can rarely be satisfied in practice. On the other hand, the effectiveness of the strained superlattice approach is limited by its narrow stressed region. To bend a threading dislocation to the plane of superlattice, the bending moment of the threading dislocation has to be very large, or equivalently, the radius of curvature of the dislocation has to be comparable to the thickness of the superlattice, typically only a few hundred Angstroms. If the dislocation can not be confined to the narrow region of the superlattice, it will propagate through the superlattice region. With a limited number of superlattice regions that one can use, the approach of a strained superlattice can only reduce the number of threading dislocations while not completely eliminating them.

The approaches of compliant substrates and stress-engineered substrates are based on a different principle from the previous approaches. A compliant substrate can be viewed as a relatively “energetically unstable” template. When stress is applied to the template by the heteroepitaxial layer, the stress is relaxed through elastic or plastic deformation of the template. As a result, the template may sacrifice itself as a sink of all the dislocations, to preserve the quality of the epitaxial layer. For stress-engineered substrates, the substrate applies a “long range” stress field to the heteroepitaxial layer to constrain dislocations. The “sign” of the applied stress field, tension or compression, is often determined by the relative thermal expansion coefficients between the epitaxial layer and the substrate since thermal stress is the most controllable means to provide the long range stress. If the thermal expansion of the epitaxial layer is greater than the substrate and the temperature is higher than the epitaxial growth temperature, the applied stress should be compressive; otherwise, the stress should be tensile.

Although the previously mentioned superlattice approach also uses stress to confine threading dislocations, the stress-engineered substrate approach is different because the stress field exists throughout the entire heteroepitaxial layer, independent of the thickness of the epitaxial layer. In contrast, the stress field in the strained superlattice only exists in the superlattice region, thus limiting its effectiveness in dislocation confinement. To create such a long range stress, thermal stress originating from different thermal expansion coefficients between the epitaxial layers and the substrate is the most effective mechanism.

However, one problem associated with thermal stress is that the “sign” of stress will be reversed when the material temperature varies from higher than to lower than the epitaxial growth temperature at which the thermal stress is zero. In other words, if the thermal stress can confine dislocations at high temperatures, the stress from the very source can “unleash” the confined dislocations at low temperatures. To overcome this problem, multi-layer substrates that can dynamically adjust the stress over different temperatures were designed. Although these designs of stress-engineered substrates solve the thermal stress sign reversal problems, they increase the substrate cost and process complexity.

### SUMMARY OF THE INVENTION

This invention discusses new solutions to the problem for stress control over a wide range of temperatures. The basic concept of dislocation filtering is similar to that of the stress-engineered substrates, but the invention combines the design of substrates, epitaxial layer structures, and growth parameters to more easily and effectively confine dislocations at all temperatures. With proper choices of the layer structure, substrate structure, and growth parameters, one can form low defect density epitaxial layers on lattice-mismatched substrates. Through interactions between dislocations and the stress field in the epitaxial layer, dislocations can be most effectively confined following the design of this invention. The design concept can be applied to any heteroepitaxial material systems as long as enough information about the dislocation structures in the epitaxial layers is available.

Briefly stated, a method for forming low defect density epitaxial layers on lattice-mismatched substrates includes confining dislocations through interactions between the dislocations and the stress field in the epitaxial layer. This method is applicable to any heteroepitaxial material systems with any degree of lattice mismatch. The method includes choosing the desired epilayer and the top substrate layer for epitaxial growth, determining the lattice constant and thermal expansion coefficient of the final epilayer and the top substrate layer, bonding an additional substrate layer under the top substrate layer to form a composite substrate so that the desired epilayer has negative (positive) or zero thermal mismatch to the composite substrate if the lattice mismatch between the epilayer and the top substrate layer is positive (negative), and choosing a buffer layer to be deposited before the desired epilayer which is lattice matched to the epilayer. The chosen buffer layer should have a positive (negative) thermal mismatch to the entire substrate if the lattice mismatch is also positive (negative).

According to an embodiment of the invention, a method for forming low defect density epitaxial layers on lattice-mismatched substrates includes (a) choosing a first epilayer and a top substrate layer for epitaxial growth; (b) determining a first lattice constant and a first thermal expansion coefficient of the first epilayer; (c) determining a second lattice constant and a second thermal expansion coefficient of the top substrate layer; (d) bonding an additional substrate layer to the top substrate layer to form a composite substrate so that the first epilayer has either positive lattice mismatch and negative or zero thermal mismatch to the composite substrate, or negative lattice mismatch and positive thermal mismatch to the composite substrate; and (e) choosing a buffer layer which is lattice matched to the first epilayer to be deposited on the composite substrate before depositing the first epilayer, wherein (i) the buffer layer has positive thermal mismatch to the composite substrate when the buffer layer and the top substrate layer have positive lattice mismatch, and (ii) the buffer layer has negative thermal mismatch to the composite substrate when the buffer layer and the top substrate layer have negative lattice mismatch.

### BRIEF DESCRIPTION OF THE DRAWINGS

FIG. 1 shows an example of the prior art of using a graded lattice constant buffer layer to reduce threading dislocations where the lattice constant of the buffer layer varies from the value of the substrate to the value of the desired epitaxial layer.

FIG. 2 shows an example of the prior art of using multiple strained superlattice regions to bend threading dislocations.

FIG. 3 shows an example of the prior art of using stress-engineered substrate to achieve a high-quality heteroepitaxial layer.

FIG. 4 shows a schematic illustration of the invention in which the substrate includes a single type of material or more than one type of material (composite substrate) in order to achieve the desired thermal expansion coefficient, where the dislocation confining buffer layer and the final epitaxial layer have the same lattice constant.

FIG. 5 shows a schematic of the visible LED (AlInGaP) layers grown on a lattice-mismatched, transparent composite substrate made of GaP and InP.

FIG. 6 shows a schematic of InP-based epitaxial layers grown on a lattice-mismatched composite substrate made of Si and Ge.

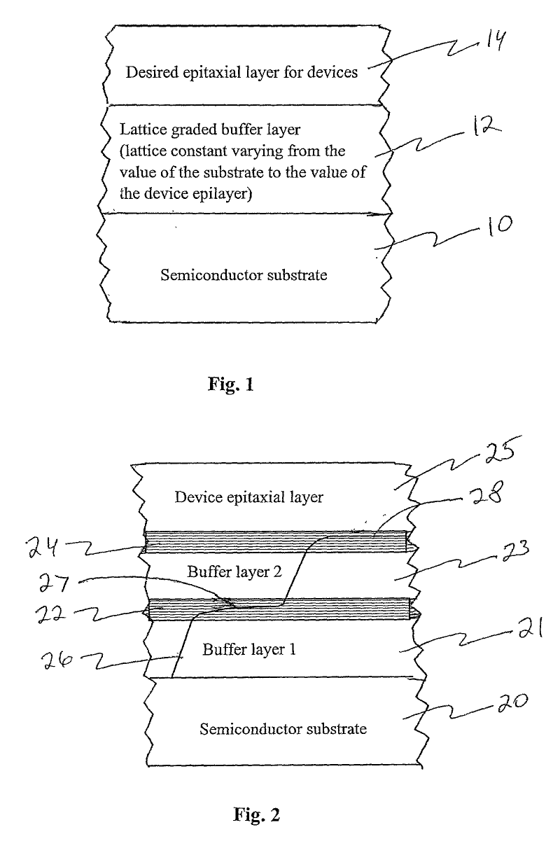

### DESCRIPTION OF THE PREFERRED EMBODIMENT

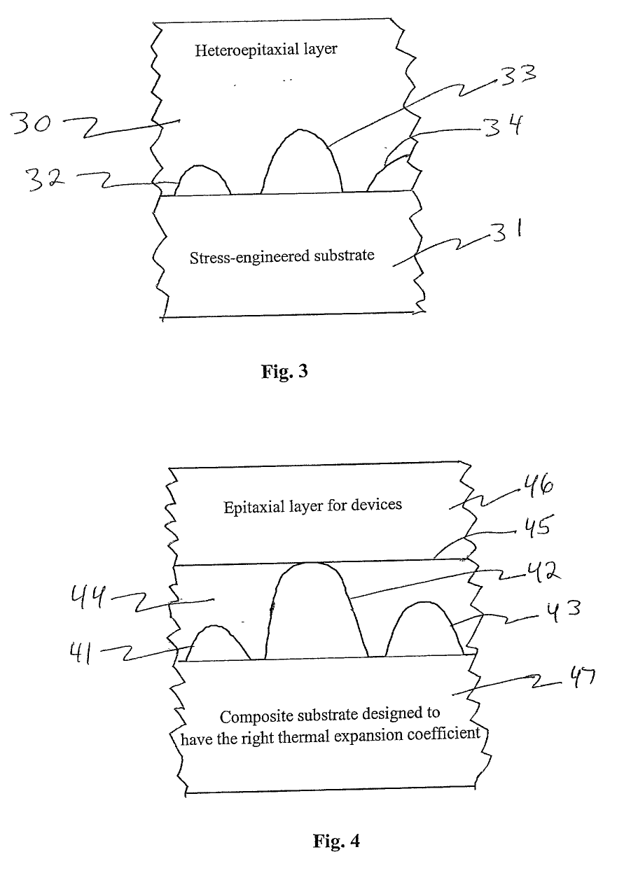

Referring to FIG. 3, assuming for illustration purposes that an epilayer (epitaxial layer) 30 has a larger lattice constant than a substrate 31 on which epilayer 30 is directly grown, then threading dislocations 32, 33, 34 can be bent under compressive stress. The bending moment and the radius of the bending curvature depends on the magnitude of stress and the relative angle between the Burgers vector and the stress. The radius of curvature can be approximately represented by Eq. 1

R=αGb/τ (1)

where R is the bending radius (radius of bending curvature), α is between 0.5 and 1, G is the shear modulus, b is the length of the Burgers vector, and τ is the shear stress in the dislocation glide plane resolved in the direction of b. Assuming the following typical numbers of α=1, b=4 Å, G=10¹¹ dynes/cm², and t=10⁸ dynes/cm², the radius of bending curvature, R, is 0.4 μm. The above calculation is approximate because it assumes the material has zero Poisson ratio, i.e., that the energy for screw and edge dislocations are the same. For a given lattice structure of the heteroepitaxial layer such as the popular zinc blende structure, the Burgers vector of most threading dislocations is known, that is, they are either 60-degree dislocations or partial dislocations. The knowledge of the possible Burgers vectors and magnitude of stress allows us to calculate the “worst case” or the “largest possible” radius of bending curvature for dislocations. Those dislocations that are bent downward may recombine and form loops at the growth interface or terminate themselves at the boundaries of the wafer. Hence when the epitaxial layer thickness is substantially greater than the “worst case” bending radius, the heteroepitaxial layer should be dislocation free in principle as shown in FIG. 3.

Once the lattice constant between the epitaxial layer and the substrate is determined, one can choose other materials of proper thermal expansion coefficients to form a composite substrate and proper epitaxial buffer layers most favorable to dislocation confinement. The methods of choosing the substrate materials have been discussed in great detail in the previous invention on stress-engineered substrates filed on Dec. 11, 1998 as U.S. application Ser. No. 09/210,166 incorporated herein by reference. For reference purposes, we summarize the design principles of stress-engineered substrates as contained therein:

(1) choose the materials for the epitaxial layers and the top layer of the substrate,

(2) compare their lattice constants and thermal expansion coefficients,

(3) if the epilayer has a larger lattice constant (positive lattice mismatch) and a larger thermal expansion coefficient (positive thermal mismatch) than the top substrate layer, bond a low thermal-expansion layer at the bottom of the substrate, and

(4) ensure that the bonded substrate layer does not significantly affect the overall thermal expansion coefficient of the substrate at a higher than the epi-growth temperature, but makes the overall thermal expansion coefficient of the substrate less than or equal to that of the epilayer at lower than the epi-growth temperature.

If principle (3) is reversed, that is, if there is negative lattice and thermal mismatch, then principle (4) becomes

(4a) ensure that the bonded substrate layer does not significantly affect the overall thermal expansion coefficient of the substrate at a higher than the epi-growth temperature, but makes the overall thermal expansion coefficient of the substrate greater than that of the epilayer at lower than the epi-growth temperature.

If only the lattice constant relation in principle (3) is reversed, then principle (4) becomes

(4b) ensure that the bonded substrate layer makes the overall thermal expansion coefficient greater than that of the epilayer at higher than the epi-growth temperature, but does not significantly affect the overall substrate thermal expansion coefficient at lower than the epi-growth temperature.

If only the thermal expansion coefficient relation in principle (3) is reversed, then principle (4) becomes

(4c) ensure that the bonded substrate layer makes the overall thermal expansion coefficient of the substrate less than that of the epilayer at higher than the epi-growth temperature, but does not significantly affect the overall substrate thermal expansion coefficient at lower than the epi-growth temperature.

In practice, it is not always easy to satisfy the above criteria. Particularly in the last two situations outlined above, stress-engineered substrates consisting of more than two materials are often needed. For example, should one want to grow AlInGaP on GaP substrates to make red, orange and yellow LEDs, the stress-engineered substrates may consist of multilayers including GaP, Si, a thin joining layer with a low melting-point, and Ge. The complicated process and use of multiple substrate layers to form a stress-engineered substrate may increase the cost and reduce the product yield. In this invention, we make use of the flexibility of selecting epitaxial buffer layers to simplify the substrate design. Our new substrate/epilayer co-design process can be summarized in the following steps:

(1) choose the desired epilayer and the top substrate layer for epitaxial growth,

(2) determine the lattice constant and thermal expansion coefficient of the final epilayer and the top substrate layer,

(3) if necessary, bond an additional substrate layer under the top substrate layer to form a composite substrate so that the desired epilayer has positive (negative) lattice mismatch and negative (positive) or zero thermal mismatch to the substrate, and

(4) choose a buffer layer to be deposited before the desired epilayer which is lattice matched to the epilayer. Furthermore, the chosen buffer layer should have a positive (negative) thermal mismatch to the entire substrate if the lattice mismatch is also positive (negative).

Steps (1) to (4) outline the procedure for co-design of the substrate and buffer layer. After the substrate and buffer layer structures are decided, the following growth procedure is preferred:

(1) grow the buffer layer on the substrate synthesized according to the above design,

(2) when the buffer layer reaches the thickness of the bending radius of most threading dislocations, perform thermal annealing (typically a few hundred degrees higher than the growth temperature),

(3) grow another buffer layer and anneal again, repeating the growth and annealing process several times until the aggregate buffer layer thickness is well above the “worst case” dislocation bending radius, and

(4) grow the desired epilayers for device applications.

Using the new design and growth procedure, one can simplify the substrate design because the confined dislocations in the buffer layer can not penetrate the epilayer/buffer layer interface.

Referring to FIG. 4, after a buffer layer 44 is grown on a substrate 47, dislocations 41, 42, 43 are confined through interactions between dislocations 41, 42, 43 and thermal stress during thermal annealing of buffer layer 44. When the material temperature falls below the growth temperature, the reversed sign of the thermal stress in buffer layer 44 may unleash the originally confined dislocations. However, since the dislocation unleashing force vanishes at an epi/buffer interface 45 and turns into a dislocation confinement force in the epitaxial layer region, those unleashed dislocations can at most reach interface 45 between epilayer 46 and buffer layer 44. If substrate 47 satisfies the necessary conditions without being formed as a composite substrate, then there is no need to bond an additional substrate layer on its bottom.

### EXAMPLE 1

Growth of AlInGaP Visible LEDs on Transparent GaP Substrates

AlInGaP compound semiconductor material is the primary material for making red/orange/yellow light-emitting diodes (LEDs). Today, the material is grown epitaxially on a lattice-matched GaAs substrate. Because the GaAs substrate is opaque to visible light, most of the light generated by AlInGaP compounds is absorbed by the substrate, which significantly reduces the brightness of the LED. It would be ideal if the AlInGaP layers were grown directly on a transparent GaP substrate, but the 4% lattice mismatch between the epilayer and GaP makes that nearly impossible. This problem can be solved using our invented method.

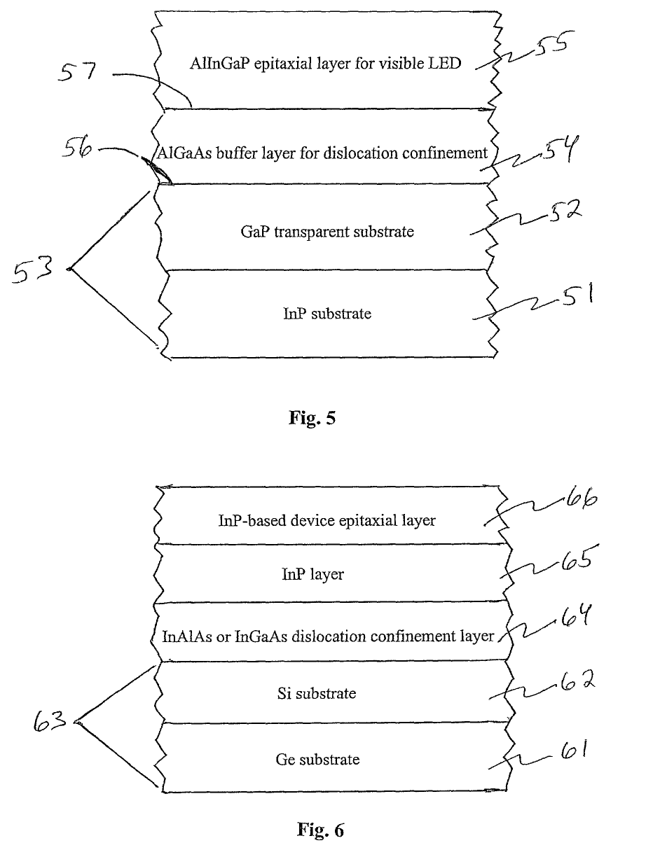

Referring to FIG. 5, an InP substrate 51 is first bonded to a backside of a GaP substrate 52 to adjust the overall thermal expansion coefficient of a composite substrate 53. After some necessary epitaxial buffer layers (not shown) usually needed to establish the surface conditions for epitaxial growth, a high Al-content AlGaAs buffer layer 54 which is lattice matched to a desired AlInGaP layer 55 is grown on GaP substrate 52, followed by high temperature (e.g., 900° C.) annealing. Because AlGaAs layer 54 has a larger thermal expansion coefficient than the GaP/InP composite substrate 53, AlGaAs layer 54 is under compression at the annealing temperature. With a 4% positive lattice mismatch, the dislocations (not shown) in AlGaAs layer 54 are bent towards an Al GaAs/GaP interface 56 through the dislocation/stress interaction.

After repeating the AlGaAs buffer layer growth and annealing process a few times so that the aggregate AlGaAs layer thickness is well above the worst case dislocation bending radius, the desired AlInGaP LED layers 55 are grown. During sample cooling, the thermal stress in AlGaAs layer 54 is reversed from compression to tension, causing possible dislocation unleashing. However, the unleashed dislocations may terminate at an AlInGaP/AlGaAs interface 57 since AlInGaP layer 55 is thermally matched to composite GaP/InP substrate 53 so the dislocation unleashing stress vanishes in AlInGaP layer 55. If we choose the GaP to InP thickness ratio greater than one, AlInGaP epilayer 55 may even be slightly under compression at lower than the growth temperature, thus making dislocations in AlGaAs buffer layer 54 even more unlikely to penetrate into AlInGaP layer 55.

Finally, our technique can not only produce high brightness red/orange/yellow AlInGaP LEDs on GaP transparent substrates but also extend the color range of the LEDs to the yellow/green regime. Unlike the conventional approach where the AlInGaP layers have to be lattice matched to GaAs, the AlInGaP layers grown in our method can have different lattice constants than GaAs. In other words, the In composition can be adjusted from about 35% to 65% as long as the buffer layer is adjusted accordingly (e.g., using AlGaAsP or AlInGaAsP to replace AlGaAs as the buffer layer) to match the chosen AlInGaP compounds. This flexibility allows us to make high brightness yellow/green LEDs that are not available today.

### EXAMPLE 2

Growth of InP on Si or Ge for Solar Cells, High-speed Transistors, and Laser Diodes.

Growing high quality InP-based compound semiconductors on Si substrates offers compelling advantages to optical and electronic devices such as solar cells, high-speed transistors, and infrared laser diodes. The cost of Si substrate is only about one thirtieth of the InP substrate, while the mechanical and thermal properties of Si wafers are far superior to InP wafers. In addition, growing InP-based electronic transistors such as heterojunction bipolar transistors (HBTs) and optical devices such as lasers, detectors, and optical modulators directly on Si facilitates integration of InP and Si devices. The main difficulty with InP-on-Si heteroepitaxial growth is again in the 7.7% positive lattice mismatch between the materials.

Referring to FIG. 6, using the invented method, we can form a composite substrate first by bonding a Ge wafer (substrate) 61 to a backside of a Si wafer (substrate) 62 for adjustment of the thermal expansion coefficient of a composite substrate 63. After standard buffer layer growth on Si substrate 62, InAlAs or InGaAs buffer layers 64 which are lattice matched to InP are grown on Si substrate 62. Many dislocations are formed in these buffer layers due to the large positive lattice mismatch to Si. High temperature thermal annealing is then conducted after growth of each InAlAs or InGaAs buffer layer 64. The positive thermal mismatch between buffer layer 64 and composite substrate 63 creates a compressive stress in the buffer layer, which bends the dislocations (not shown) downward. After repeating the buffer layer growth and thermal annealing process several times, we grow an InP epitaxial layer 65. Finally, InP-based compound device layers 66 are grown on top InP layer 65.

During sample cooling, the sign reversal of the thermal stress in InAlAs/InGaAs buffer layer 64 may unleash the dislocations. However, those unleashed dislocations can not propagate through InP layer 65 because InP layer 65 has zero stress or compressive stress at lower than the growth temperature due to its equal or smaller thermal expansion coefficient difference from the composite Si/Ge substrate 63. If dislocations can not penetrate InP layer 65, they can not enter the device epitaxial layers 66 on top of InP layer 65.

This statement is particularly true when InP layer 65 is thick enough (e.g., 2 μm) to isolate the stress effect from the top device layers 66. The above discussion assumes that one wants to grow InP-based material on the Si-side of the Si/Ge composite wafer. It is also possible to grow the same structure on the Ge-side of such a wafer. In fact, two advantages of growing InP-based materials on the Ge-side of the wafer are a smaller lattice mismatch (3.7% as opposed to 7.7%) and the availability of an initial defect-free GaAs buffer layer on Ge. As a result, all InP-based epilayers may be grown on a GaAs buffer layer for better nucleation and fewer antiphase domain problems. It should also be noted that although we have referred to InP-based materials as having the same lattice constant of InP (i.e., lattice matched), it does not have to be so. The invented technique applies as well to materials containing In or P but not necessarily matched to InP. For example, InGaAsP or InGaAlAs quaternary compounds with lattice constants 1 to 2% smaller or greater than InP can also be grown on the Si/Ge substrate using the disclosed technique.

Furthermore, the same principle can be applied to many other material systems including Sb-based semiconductors such as GaSb, InSb, or InGaSbAs, etc., N-based semiconductors including (In)GaN, AlGaN, AlN, BN, etc., As-based semiconductors including N-doped GaAs, InGaAs, etc., II-VI compound semiconductors such as ZnSe, Si-based semiconductors such as SiGe and C-doped SiGe, C-based semiconductors such as SiC, and so on.

Accordingly, it is to be understood that the embodiments of the invention herein described are merely illustrative of the application of the principles of the invention. Reference herein to details of the illustrated embodiments are not intended to limit the scope of the claims, which themselves recite those features regarded as essential to the invention.

What is claimed is:

1. A method for forming low defect density epitaxial layers on lattice-mismatched substrates, comprising the steps of:
a) choosing a first epilayer and a top substrate layer for epitaxial growth;
b) determining a first lattice constant and a first thermal expansion coefficient of said first epilayer;
c) determining a second lattice constant and a second thermal expansion coefficient of said top substrate layer;
d) bonding an additional substrate layer to said top substrate layer to form a composite substrate so that said first epilayer has either positive lattice mismatch and negative or zero thermal mismatch to said composite substrate, or negative lattice mismatch and positive or zero thermal mismatch to said composite substrate; and
e) choosing a buffer layer which is lattice matched to said first epilayer to be deposited on said composite substrate before depositing said first epilayer, wherein
said buffer layer has positive thermal mismatch to said composite substrate when said buffer layer and said top substrate layer have positive lattice mismatch, and
said buffer layer has negative thermal mismatch to said composite substrate when said buffer layer and said top substrate layer have negative lattice mismatch.

2. A method according to claim 1, further comprising the steps of:
growing said buffer layer on said composite substrate;
thermally annealing said buffer layer and composite substrate when said buffer layer reaches a thickness of a bending radius of at least a majority of threading dislocations present in said buffer layer; and
repeating the steps of growing and thermally annealing until an aggregate buffer layer thickness is above said bending radius of all threading dislocations present in said buffer layer.

3. A method according to claim 2, wherein said buffer layer is grown on said top substrate layer.

4. A method according to claim 2, wherein said buffer layer is grown on said additional substrate layer.

5. A method according to claim 2, further comprising the step of growing said first epilayer on said buffer layer.

6. A method according to claim 5, further comprising the step of growing a second epilayer on said first epilayer.

7. A method according to claim 1, wherein said top substrate layer is of a material selected from the group consisting of GaP, Si, and Ge.

8. A method according to claim 7, wherein said additional substrate layer is of a material selected from the group consisting of InP, Ge, and Si.

9. A method according to claim 8, wherein said buffer layer is of a material selected from the group consisting of AlGaAs, InAlAs, and InGaAs.

10. A method according to claim 9, wherein said first epilayer is of a material selected from the group consisting of AlInGaP and InP.

11. A method according to claim 10, wherein said second epilayer is InP-based.

12. A method for forming low defect density epitaxial layers on lattice-mismatched substrates, comprising the steps of:
a) choosing a first epilayer and a substrate for epitaxial growth;
b) determining a first lattice constant and a first thermal expansion coefficient of said first epilayer;
c) determining a second lattice constant and a second thermal expansion coefficient of said substrate;
d) ensuring that said first epilayer has either positive lattice mismatch and negative or zero thermal mismatch to said substrate, or negative lattice mismatch and positive or zero thermal mismatch to said substrate; and
e) choosing a buffer layer which is lattice matched to said first epilayer to be deposited on said substrate before depositing said first epilayer, wherein
said buffer layer has positive thermal mismatch to said substrate when said buffer layer and said substrate have positive lattice mismatch, and
said buffer layer has negative thermal mismatch to said substrate when said buffer layer and said substrate have negative lattice mismatch.

13. A method according to claim 12, further comprising the steps of:
growing said buffer layer on said substrate;
thermally annealing said buffer layer and substrate when said buffer layer reaches a thickness of a bending radius of at least a majority of threading dislocations present in said buffer layer; and
repeating the steps of growing and thermally annealing until an aggregate buffer layer thickness is above said bending radius of all threading dislocations present in said buffer layer.

14. A product made according to the method of claim 1.

15. A product made according to the method of claim 2.

16. A product made according to the method of claim 12.

17. A product made according to the method of claim 13.
